(19) United States
(12) Patent Application Publication
(10) Pub. No.: US 2025/0098367 A1
(43) Pub. Date: Mar. 20, 2025

(54) RED LIGHT-EMITTING DIODE

(71) Applicant: SUNDIODE KOREA, Seoul (KR)

(72) Inventors: James Chinmo KIM, Mountain View, CA (US); Sungsoo YI, Sunnyvale, CA (US)

(21) Appl. No.: 18/404,884

(22) Filed: Jan. 4, 2024

(30) Foreign Application Priority Data
Sep. 20, 2023 (KR) 10-2023-0125225

(51) Int. Cl. H01L 33/06; H01L 33/32

(52) U.S. Cl. CPC H10H 20/812; H10H 20/825

(57) ABSTRACT

A red light-emitting diode utilizing electron tunneling is disclosed. Tunneling occurs between two well layers arranged around a barrier layer due to the wave-like properties of electrons. Due to the unique properties and strain of the crystal structure, the polarization in the well layer causes displacement of electrons and holes. The electrons tunnel through the barrier layer and recombine with holes in the valence band on the opposite side.

### CROSS-REFERENCE TO RELATED PATENT APPLICATION

This application claims the benefit of Korean Patent Application No. 10-2023-0125225, filed on Sep. 20, 2023, in the Korean Intellectual Property Office, the disclosure of which is incorporated herein in its entirety by reference.

### BACKGROUND OF THE INVENTIVE CONCEPT

### 1. Field of the Inventive Concept

The present inventive concept is related to a red light-emitting diode, and more specifically, to a red light-emitting diode that is based on gallium nitride (GaN) and utilizes a tilted energy band of a well layer.

### 2. Description of the Related Art

Most red light-emitting diodes adopt a structure that uses AlGaInP as the active layer. AlGaInP is formed by epitaxially growing on a GaAs substrate. AlGaInP is known to have high external quantum efficiency (EQE) and is recognized as a material that can emit infrared or red light. AlGaInP and GaAs both have the face-centered cubic (FCC) crystal structure.

However, AlGaInP-based red light-emitting diodes have the following disadvantages.

The first disadvantage is a decrease in light-emission efficiency due to surface recombination resulting from decreasing the size of a device. This has recently become a particularly important issue for micro-LEDs due to the associated size reduction. While forming an AlGaInP-based red light-emitting diode on a micron scale using a chip fabrication process, peripheral surface areas of the device increasingly interact with the carriers as the device size become comparable to the carrier diffusion length. As a result, recombination can not only occur within the junction, but also on the surface, resulting in a decrease in light-emission efficiency.

The second disadvantage is a decrease in light-emission efficiency due to the temperature characteristics of the AlInGaP light-emitting diodes. It is well known in the art that when each 1° C. increase in the junction temperature within the light-emitting layer, the EQE decreases by approximately 1%.

Thus, the AlGaInP-based red light-emitting diodes have known significant drawbacks as micro-sized light-emitting diodes operating in environments with increasing temperatures. As an alternative to the AlGaInP-based red light-emitting diodes, GaN-based red light-emitting diodes are actively being considered.

GaN-based light-emitting layers are used for producing blue or green light-emitting diodes. GaN-based materials have a hexagonal crystal structure and are grown on sapphire substrates through the MOCVD process. Moreover, the emission wavelength of GaN is determined by the indium (In) content. For example, as the indium content increases in InₓGa₁₋ₓN, the emission wavelength becomes longer, theoretically allowing for the realization of red light with enough indium.

However, as the indium content increases, there arises an issue with the agglomeration and phase separation within the InGaN crystal, and the crystallinity of the compound semiconductor is deteriorated due to indium's larger atomic size compared to gallium (Ga). The reduced crystallinity in the compound semiconductor creates defects within the crystal structure, and results in problems such as a decrease in light-emission efficiency and the associated generation of heat due to the non-radiative recombination.

Another issue of GaN light-emitting layers with incorporated indium is the internal polarization field. The internal polarization field causes a tilted energy band that can interfere with the recombination of electrons and holes within the layer.

FIG. 1 is a bandgap diagram illustrating the internal polarization field in an InGaN light-emitting layer according to prior art.

In FIG. 1, a quantum well structure is shown. The quantum well structure includes a well layer 20 situated between two barrier layers 10 and 30. The barrier layers 10 and 30 have a higher bandgap than the well layer 20 and confine electrons and holes in the well layer 20 to result in light emission therewithin. As the In content increases, polarization intensifies along the growth direction of the well layer 20. The intensified polarization is due to dipoles forming within the crystal along the c-axis of the crystal during formation of the InGaN by a c-axis growth. As the indium content increases, polarization intensifies, and the intensifying polarization leads to the intensification of an internal electric field E_{POL}. The internal electric field E_{POL} caused by the polarization in turn creates a tilted energy band within the well layer 20. For the electrons and holes generated by an applied external electric field (i.e., an external bias), electrons move to the lowest-energy region of the conduction band to be densely populated near the interface between the first barrier layer 10 and the well layer 20. Contrarily, holes are concentrated in the highest-energy region of the valence band and densely populated near the interface between second barrier layer 30 and the well layer 20. The structure described above is interpreted as an energetic barrier due to the tilted band resulting from the polarization that inhibits recombination of electrons and holes.

For the foregoing reasons, the GaN-based light-emitting layer for generating red light has a very low external quantum efficiency. It is well known that InGaN light-emitting layer for red light has an external quantum efficiency of less than 3%.

However, compared to light-emitting layers of AlGaInP, the GaN-based red light-emitting diodes exhibit a significantly lower decrease in light emission efficiency associated with increased surface recombination due to device size reduction. The GaN-based red light-emitting diodes also exhibit relatively superior temperature characteristics, making them highly suitable for micro-LEDs. However, for the reasons indicated above regarding the energetic barrier against recombination and the resulting low external quantum efficiency, the GaN-based red light-emitting diodes have not yet been widely adopted in micro-LEDs. Therefore, the development of GaN-based red light-emitting diodes with high external quantum efficiency is required for the application to micro-sized light-emitting devices and displays thereof.

### SUMMARY OF THE INVENTIVE CONCEPT

The present inventive concept has been made in order to solve the above-described problems associated with the prior art, and an object of the present inventive concept is to provide a red light-emitting diode that uses recombination of electrons tunneling from one well layer to another through a barrier.

To achieve the above-mentioned object, the present inventive concept provides a red light-emitting diode comprising: a first well layer; a barrier layer formed on the first well layer and having a higher bandgap than the first well layer; and a second well layer formed on the barrier layer and having a lower bandgap than the barrier layer, wherein the first well layer and the second well layer have a tilted band structure, and wherein electrons in the first well layer recombine with holes in the second well layer through tunneling to perform a light emission operation.

The above-described object of the present inventive concept can also be achieved by providing a red light-emitting diode comprising: a first well layer made of InGaN; a barrier layer formed on the first well layer, through which electrons of the conduction band in the first well layer can tunnel; and a second well layer made of InGaN and formed on the barrier layer, where the tunneling electrons in the first well layer recombine with holes, wherein the concentration of indium in the first well layer increases toward the barrier layer, and the concentration of indium in the second well layer also increases toward the barrier layer.

According to the present inventive concept as described above, the well layers act as a donor layer for either electrons or holes. In particular, the electrons tunnel through the barrier layer and recombine with holes in the other well layer adjacent to the barrier layer to perform a light emission operation. In other words, light emission within a single well layer is not primarily governed by the light emission mechanism associated with the recombination of electrons and holes in the same well layer; rather, it is governed by the light emission mechanism associated with the recombination of tunneling electrons with the holes in the other well which are constrained near the barrier layer by the polarization barrier of the well layer. This means that it is possible to overcome limitations on the thickness of the well layer that impede achieving a high external quantum efficiency and to create a multi-quantum well structure.

By adjusting the thickness of the barrier layer and the barrier height, the electrons and holes in the well layers can be optimized to recombine with a high probability, thereby increasing external quantum efficiency. In particular, efforts to remove the polarization barrier are not needed for single crystal growth, and instead, an advantageous increase in the light-emission efficiency results due to utilizing the polarization barrier. Furthermore, since the light emission mechanism does not primarily rely on the recombination of electrons and holes in the same well layer, limitations on the thickness of the well layer are eliminated, facilitating the formation of the well layers.

### BRIEF DESCRIPTION OF THE DRAWINGS

The above and other features and advantages of the present inventive concept will become more apparent by describing in detail exemplary embodiments thereof with reference to the attached drawings.

FIG. 1 is a bandgap diagram illustrating the internal polarization phenomenon of an InGaN light-emitting layer according to prior art.

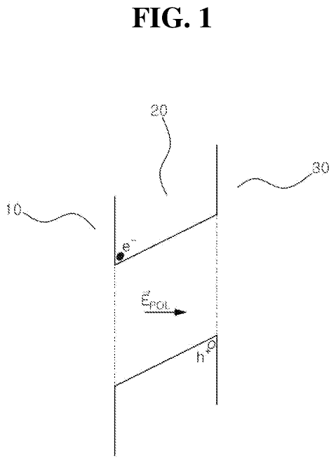

FIG. 2 is a bandgap diagram of a red light-emitting diode using a tilted band according to a first embodiment of the present inventive concept.

FIG. 3 is a graph illustrating the tunneling probability of electrons depending on the type and thickness of the barrier layer according to the first embodiment of the present inventive concept.

FIG. 4 is a graph illustrating the probability of recombination of electrons and holes in a well layer depending on the thickness of the well layer according to the first embodiment of the present inventive concept.

FIG. 5 shows a cross-sectional view and a bandgap diagram of a red light-emitting diode according to a second embodiment of the present inventive concept.

FIG. 6 is a bandgap diagram of a red light-emitting diode using a tilted band according to the second embodiment of the present inventive concept.

### DETAILED DESCRIPTION OF THE INVENTIVE CONCEPT

As the present inventive concept allows for various changes and numerous embodiments, particular embodiments will be illustrated in the drawings and described in detail in the description. However, this is not intended to limit the present inventive concept to particular modes of practice, and it is to be appreciated that all changes, equivalents, and substitutes that do not depart from the spirit and technical scope of the present inventive concept are encompassed by the present inventive concept. In the drawings, like reference numerals have been used throughout to designate like elements.

Unless defined otherwise, all terms used herein including technical or scientific terms have the same meaning as those generally understood by those skilled in the art to which the present inventive concept pertains. It will be further understood that terms defined in dictionaries that are commonly used should be interpreted as having meanings that are consistent with their meanings in the context of the relevant art and should not be interpreted as having ideal or excessively formal meanings unless clearly defined in the present application.

Hereinafter, preferred embodiments of the present inventive concept will be described in more detail with reference to the accompanying drawings.

### First Embodiment

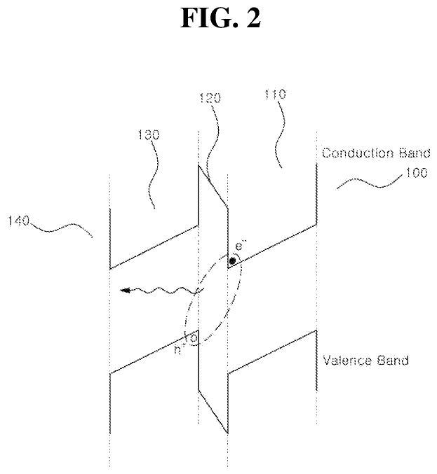

FIG. 2 is a bandgap diagram of a red light-emitting diode using a tilted band according to a first embodiment of the present inventive concept.

Referring to FIG. 2, a first semiconductor layer 100, a first well layer 110, a barrier layer 120, a second well layer 130, and a second semiconductor layer 140 are illustrated. The bandgap diagram shows that the first semiconductor layer 100 and so on have been grown from right to left, but the red light-emitting diode is actually formed by c-axis growth on a substrate such as sapphire. Moreover, it is assumed that the compound semiconductors illustrated in FIG. 2 have a uniform dopant concentration for n- and p-type semiconductor layers, and indium is evenly distributed in alloy layers such as InGaN.

In the bandgap diagram, the polarization direction may vary depending on whether the growth end is terminated with gallium (Ga) or nitrogen (N). In the case of GaN-based compound semiconductors with c-axis growth, polarization inevitably occurs, resulting in a tilted band.

The two types of polarization effects are spontaneous polarization and piezoelectric polarization.

Spontaneous polarization is caused by the inherent crystal structure resulting from the c-axis growth during formation of GaN-based single crystals. In other words, if the growth end of a single crystal is the gallium (Ga) surface (including the indium (In) surface, hereinafter the same), polarization directed from the growth end to the growth initiation point is formed and the internal electric field is in the opposite direction. Contrarily, if the growth end is the nitrogen (N) surface, polarization directed from the growth initiation point to the growth end is formed, and the internal electric field is in the opposite direction.

Piezoelectric polarization is caused by strain that is formed within a layer or applied externally. If the growth end of the layer is the gallium (Ga) surface with an applied compressive stress, polarization is directed toward the growth end point, and the internal electric field is in the opposite direction. If the growth end of the film is the Ga surface with an applied tensile stress, polarization is toward the growth initiation point, and the internal electric field is in the opposite direction. Furthermore, if the growth end of the layer is the nitrogen (N) surface with an applied compressive stress, the polarization is toward the growth initiation point, and the internal electric field is in the opposite direction. In addition, if the growth end of the layer is the nitrogen (N) surface with an applied tensile stress, the polarization is directed toward the growth end point, and the internal electric field is directed toward the growth initiation point.

In all cases, a tilted band is formed within the well layer. However, for convenience of explaining the present inventive concept, the growth direction of the layer is assumed to be from right to left. Moreover, the internal electric field due to the polarization is set to point to the right. Furthermore, the external bias for light emission is assumed to be from left to right.

In FIG. 2, the first semiconductor layer 100 is an n-type semiconductor layer and has a higher bandgap than the well layers 110 and 130. Preferably, the n-type semiconductor layer has Si doping and may be made of GaN. Optionally, the first semiconductor layer 100 may be InGaN with a lower indium (In) content than the well layers 110 and 130. Electrons are supplied through the first semiconductor layer 100.

The first well layer 110 has a tilted band structure toward the barrier layer 120.

The first well layer 110 is made of InGaN and contains indium (In) for red-light emission. If the average composition of the first well layer 110 is assumed to be InₓGa₁₋ₓN, it is desirable for x to be in the range of 0.1 to 0.7. Assuming that the internal electric field due to the polarization is directed toward the first semiconductor layer 100, the conduction band of the first well layer 110 has lower energy at the interface with the barrier layer 120, which is the growth end. Therefore, electrons in the conduction band of the first well layer 110 are predominantly distributed in the interface region with the barrier layer 120 due to the tilted band caused by the internal electric field.

Furthermore, holes in the first well layer 110 are concentrated at the interface with the first semiconductor layer 100 according to the tilted band. This is because holes tend to be predominantly distributed in the highest-energy region of the valence band.

The barrier layer 120 is formed on the first well layer 110 and has a higher bandgap than the first well layer 110. The barrier layer 120 may be made of InGaN, GaN, or AlGaN to have a higher bandgap than the first well layer 110. In addition, the barrier layer 120 has a thickness through which electrons in the conduction band of the first well layer 110 can tunnel. The thinner the barrier layer 120 is, the easier it is for electrons in the conduction band of the first well layer 110 to tunnel, and the smaller the bandgap energy of the barrier layer 120 is, the easier it is for electrons to tunnel.

The second well layer 130 is formed on the barrier layer 120. The second well layer 130 preferably has the same material as the first well layer 110. However, if necessary, the fraction of indium (In) in the second well layer 130 may be set differently from that of the first well layer 110. The second well layer 130 containing InGaN has a tilted band similar to that of the first well layer 110. In other words, it has an internal electric field directed toward the barrier layer 120. Therefore, the band has a positive slope toward the barrier layer 120.

For example, it is assumed that the first well layer 110 is n-doped, and the second well layer 130 is p-doped. In the case of the first well layer 110, the majority carriers are electrons, and along the tilted band of the conduction band, electrons are predominantly distributed in the region adjacent to the barrier layer 120. The minority carriers, which are holes, are predominantly distributed in the highest-energy region of the valence band, farthest from the barrier layer 120. Therefore, the probability of recombination of electrons and holes within the same well layer becomes quite low.

Expanding upon this, the electrons of the first well layer 110 and the holes of the second well layer 130 are predominantly distributed at the interfaces with the barrier layer 120, with the barrier layer 120 interposed therebetween.

The second semiconductor layer 140 is formed on the second well layer 130. The second semiconductor layer 140 preferably has a p-type conductivity. For example, the second semiconductor layer 140 may be made of GaN or InGaN. If the second semiconductor layer 140 is made of InGaN, the fraction of indium (In) is preferably lower than that of the second well layer 130. In other words, the second semiconductor layer 140 has a higher bandgap than the second well layer 130 or the first well layer 110 and acts as a source of holes. To this end, the second semiconductor layer 140 is doped with Mg.

In this embodiment, the active layer is shown as consisting of two well layers 110 and 130 and one barrier layer 120, but it should be understood that those skilled in the art can create a multi-quantum well structure using more well layers and barrier layers. In other words, a structure where additional barrier layers and well layers are formed on the second well layer 130 also falls within the scope of the present inventive concept.

In the structure illustrated in FIG. 2, the tilted band of the well layers 110 and 130 acts as a barrier for carriers that need to recombine, creating a type of polarization barrier. Therefore, the probability of recombination of electrons and holes within the same well layer is reduced, which reduces the external quantum efficiency of GaN-based red light-emitting diodes. This is a fundamental phenomenon that occurs when well layers are formed with InGaN. Due to the inherent polarization effect resulting from the c-axis growth of InGaN, this is an unavoidable phenomenon, and it is practically impossible to flatten the tilted band of the well layers.

Therefore, the inventors of the present inventive concept have conducted research on the mechanism and analysis models of existing light-emitting structures and proposed a new model and light-emission mechanism. In other words, a red light-emitting diode is proposed that overcomes the polarization barrier and enhances the light-emission efficiency through a new model, rather than a conventional model where electron and hole particles recombine within the well layers located between the two barrier layers. The core of the proposal is to interpret electrons and holes as wave functions and to ask whether or not the electrons or holes within one of the well layers also exist in the opposite well layer due to their wave-functional properties for recombining with carriers in the opposite well layer.

To this end, the Wentzel-Kramers-Brillouin (WKB) approximation is used. The WKB approximation is a method used to solve the Schrödinger equation under the assumption that pure quantum mechanical effects are small and the amplitude or phase of the wave function is almost constant. In particular, the WKB approximation is useful in explaining effects that cannot be accounted for by classical mechanics, such as tunneling. In the tunneling region, the wave function has an exponential form, and the square of the absolute value of the wave function corresponds to the probability density. If the boundary conditions are set appropriately for the bandgap structure in FIG. 2, a simplified formula based on the WKB approximation can be derived.

In FIG. 2, the probability that the electrons distributed at the interface between the first well layer 110 and the barrier layer 120 will recombine with the holes of the second well layer 130 on the opposite side may be determined by Equation 1 below. However, it is important to note that the Equation 1 accurately represents the probability that the electrons in the conduction band of the first well layer will overcome the energy barrier of the barrier layer and exist in the conduction band of the second well layer. In the present inventive concept, it is assumed that carriers concentrated at the interface of the barrier layer exist in the same well layer, but that the recombination of electrons and holes is driven when the electrons from the first well layer are also distributed in the conduction band of the interface region where the second well layer is in contact with the barrier layer according to the Equation 1. The interpretation of the equation remains the same as described above.

$${T}_{e , SIR} \approx exp [ - 2 \sqrt{\frac{2 {m}_{e} {L}^{2}}{{ℏ}^{2}} {E}_{bh}} ] \qquad [ Equation 1 ]$$

In Equation 1, T_{e,SIR} represents the probability that the electrons in the conduction band of the first well layer 110 will recombine with the holes in the second well layer 130 or the probability that the electrons from the first well layer 110 distributed at the interface with the barrier layer 120 will be distributed at the interface between the second well layer 130 and the barrier layer 120. Moreover, mₑ represents the effective mass of electron, L is the thickness of the barrier layer 120, and E_{bh} is the energy difference of the barrier layer 120 as seen by the electrons in the first well layer 110. Furthermore, ℏ is the reduced Planck's constant h/(2π), and h is the Planck's constant.

In Equation 1, the barrier layer 120 is set as GaN, and the thickness of the barrier layer 120 is set 0.5 nm. The first well layer 110 is InGaN, and the fraction of indium (In) is adjusted to emit red light with a wavelength of 620 nm. For convenience of explanation, the effective mass of the electron, mₑ, is set to have a value of 20% compared to the rest mass of electron. When these boundary conditions are applied, the following Equation 2 is derived:

$${T}_{e , SIR} \approx exp [ - 2 \sqrt{\frac{2 ( 1 \times {10}^{5} eV ) {( 0.5 nm )}^{2}}{{( 197 eV nm )}^{2}} ( 0.7 eV )} ] \approx 14.7 \% \qquad [ Equation 2 ]$$

That is, under the above boundary conditions, the probability that the electrons distributed at the interface of the first well layer 110 will exist at the interface of the opposite second well layer 130 and recombine with holes is 14.7%. This corresponds to the recombination rate.

Furthermore, the probability that the holes distributed at the interface of the second well layer 130 of FIG. 2 will tunnel through the barrier layer 120 and be distributed at the interface of the first well layer 110 may be determined by Equation 3 below:

$${T}_{h , SIR} \approx exp [ - 2 \sqrt{\frac{2 {m}_{h} {L}^{2}}{{ℏ}^{2}} {E}_{bh}} ] \qquad [ Equation 3 ]$$

In Equation 3, T_{h,SIR} represents the probability that the holes in the valence band of the second well layer 130 will recombine with the electrons in the first well layer 110 or the probability that the holes from the second well layer 130 distributed at the interface with the barrier layer 120 will be distributed at the interface between the first well layer 110 and the barrier layer 120. Moreover, mₕ represents the effective mass of the hole, and E_{bh} represents the height of the energy barrier of the barrier layer 120 as seen by the holes in the second well layer 130. In this embodiment, the band offset is set to 50:50. This means that the height of the barrier layer 120 as seen by the electrons distributed at the interface of the first well layer 110 is equal to the height of the barrier layer 120 as seen by the holes distributed at the interface of the second well layer 130.

Using the boundary conditions of Equation 2 above, the probability that the holes at the interface of the second well layer 130 will recombine with the electrons at the interface of the first well layer 110 may be determined by Equation 4 below:

$${T}_{h , SIR} \approx exp [ - 2 \sqrt{\frac{2 ( 7.2 \times {10}^{5} eV ) {( 0.5 nm )}^{2}}{{( 197 eV nm )}^{2}} ( 0.7 eV )} ] \approx 0.6 \% \qquad [ Equation 4 ]$$

As shown in Equation 4, the probability that the holes at the interface of the second well layer 130 will tunnel through the barrier layer 120 and recombine with the electrons at the interface of the first well layer 110 is less than 1%.

Moreover, the probability that the electrons and holes within the first well layer 110 will recombine each other may be determined by Equation 5 below:

$${T}_{e , POL} \approx exp [ - 2 \sqrt{\frac{2 {m}_{e} {L}^{2}}{{ℏ}^{2}} \frac{{E}_{POL}}{2}} ] \qquad [ Equation 5 ]$$

In Equation 5, T_{e,POL} represents the probability that the electrons in the first well layer 110 will recombine with the holes in the first well layer 110. The boundary conditions are set such that the electrons tunnel through the internal polarization barrier and recombine with the holes distributed at the interface of the first semiconductor layer 100. Here, E_{POL} corresponds to the difference in the tilted band of the first well layer 110, and E_{POL}/2 is applied as an energy barrier, assuming an equivalent barrier with no tilted band. Moreover, in Equation 5, L represents the thickness of the first well layer 110.

If the thickness of the first well layer 110 is set to 1.5 nm and the same boundary conditions as Equation 2 above are applied, the probability that the electrons and holes in the first well layer 110 will recombine may be determined by Equation 6 below:

$${T}_{e , POL} \approx exp [ - 2 \sqrt{\frac{2 ( 1 \times {10}^{5} eV ) {( 1.5 nm )}^{2}}{{( 197 eV nm )}^{2}} ( \frac{0.7}{2} eV )} ] \approx 1.7 \% \qquad [ Equation 6 ]$$

In Equation 6, T_{e,POL} represents the probability that the electrons in the first well layer 110 will recombine with the holes in the first well layer 110. As seen in Equations 5 and 6 above, it is evident that the probability that the electrons and holes in a single well layer recombine is extremely low due to the polarization barrier, regardless of the thickness and energy of the barrier layer 120. Furthermore, it can be seen that as the thickness of the well layer increases, the polarization barrier increases to result in a rapid reduction in the probability of recombination of electrons and holes.

These results indicate the challenges faced by those skilled in the art in manufacturing the active layers of GaN-based red light-emitting diodes. In other words, the thickness of the well layers within the active layer having barrier layer and well layer is restricted to be about 2 nm to 2.5 nm. Within these limits, as the thickness of the well layers where the light emission takes place increases, a polarization barrier is formed within the well layer, leading to a decrease in the recombination probability. Furthermore, it is known in the art that the fabrication of GaN-based red light-emitting diodes with practical multi-quantum well structures is extremely challenging. In other words, when the repeated structure of the well layer and barrier layer is accumulated, compressive stress increases in compound single crystals, and due to the effects of piezoelectric polarization, probability of recombination of electrons and holes is significantly reduced.

However, the present inventive concept does not rely primarily on the light emission through the recombination of electrons and holes within the same well layer but uses the tunneling of electrons through the barrier layer. This is achieved through the probability density as described in Equation 1. In other words, the present inventive concept induces the recombination between the electrons that are densely distributed due to the polarization barrier in the first well layer adjacent to the interface with the center barrier layer and the holes densely distributed due to the polarization barrier in the second well layer opposite the first well layer. Therefore, the light-emitting structure of present inventive concept offers the advantage of increasing light-emission efficiency as the polarization in the well layer deepens.

In particular, since the present inventive concept does not rely primarily on the recombination of electrons and holes within the same well layer, there is no limitation on the thickness of the well layer. Therefore, it becomes possible to create practical multi-quantum well structures with higher probability of recombination of electrons and holes.

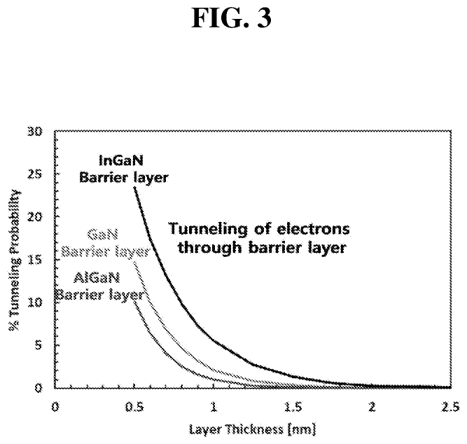

FIG. 3 is a graph illustrating the tunneling probability of electrons depending on the type and thickness of the barrier layer according to the first embodiment of the present inventive concept.

Referring to FIG. 3, the x-axis represents the thickness of the barrier layer, and the y-axis represents the probability that the electrons will tunnel through the barrier layer and exist at the interface of the well layer on the opposite side for recombination.

There are three types of barrier layers: AlGaN, GaN, and InGaN. AlGaN is designed with an energy barrier of 4 eV by controlling the mole fraction of aluminum (Al). InGaN is designed with an energy barrier of 2.75 eV by controlling the mole fraction of indium (In). GaN has a well-known energy barrier of 3.4 eV. The well layer is designed to emit red light with a wavelength of 620 nm using InGaN.

When applying Equation 2 above, the energy difference E_{bh} of the barrier layer, as seen by the electrons at the interface of the well layer, is applied based on the assumption of a 50/50 band offset. Specifically, the E_{bh} of AlGaN is (4-2)/2 eV, the E_{bh} of InGaN is (2.8-2)/2 eV, and the E_{bh} of GaN is (3.4-2)/2 eV.

As illustrated in FIG. 3, as the height of the energy barrier of the barrier layer increases, the recombination probability due to tunneling decreases. Likewise, as the thickness of the barrier layer increases, the recombination probability due to electron tunneling also decreases.

The calculation in FIG. 3 is not performed when the thickness of the barrier layer is less than 0.5 nm. This is due to the fact that the c-axis lattice constants of AlGaN, GaN, and InGaN are roughly 0.5 nm, 0.51 nm, and 0.53 nm, respectively. If the thickness of the barrier layer is less than 0.5 nm, it would be less than the single-crystal lattice constant, making it practically meaningless.

When AlGaN is used as the barrier layer, it shows a recombination probability of about 1% at a thickness of 1 nm and about 10% at a thickness of 0.5 nm. When GaN is used as the barrier layer, it shows a recombination probability of 2% at a thickness of 1 nm and about 15% at a thickness of 0.5 nm. When InGaN is used as the barrier layer, it shows a recombination probability close to 6% at a thickness of 1 nm and about 24% at a thickness of 0.5 nm.

Ultimately, it is necessary to use InGaN as the barrier layer and design the barrier layer to have a thickness of either one or two lattices in the c-axis direction.

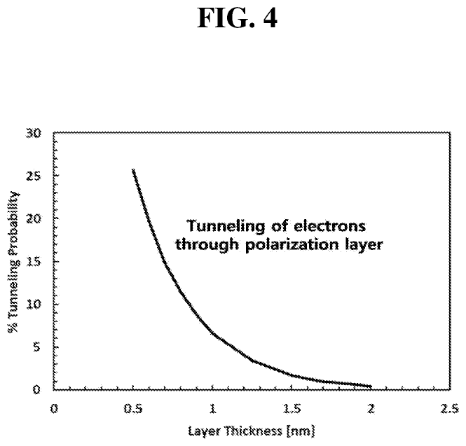

FIG. 4 is a graph illustrating the probability of recombination of electrons and holes in a well layer depending on the thickness of the well layer according to the first embodiment of the present inventive concept.

Referring to FIG. 4, the x-axis represents the thickness of the well layer, and the y-axis represents the probability of recombination of electrons and holes within the well layer. As shown in FIG. 3, the well layer is designed to be made of InGaN and emit red light with a wavelength of 620 nm by adjusting the content of indium (In). The barrier layer is designed to have a sufficient thickness so that tunneling of electrons through the barrier layer is insignificant.

The data illustrate that the polarization barrier formed within the well layer due to the c-axis growth leads to a rapid decrease in the tunneling probability of electrons through the polarization barrier as the thickness of the well layer increases. This result reflects the challenges faced by the LED industry in the production of GaN-based red light-emitting diodes. That is, for well layer thickness exceeding 2 nm, the data confirm the prediction that the light emission efficiency due to recombination of electrons and holes within the same well layer becomes extremely low. For example, for a well-layer thickness of 2 nm, the recombination rate is less than 0.5%.

In FIG. 3, if InGaN is selected as the barrier layer, for a barrier-layer thickness of 0.5 nm to 1 nm and a well-layer thickness of 1.5 nm or more, the contribution rate to light emission associated with the recombination within the well layer itself is less than about 22%. Here, the contribution rate to light emission is a value obtained by dividing the recombination probability due to a specific mechanism by the total recombination probability. For example, the contribution rate to light emission associated with the tunneling of electrons in the present inventive concept is T_{e,SIR}/(T_{e,SIR}+T_{e,POL}).

Specifically, if the thickness of the well layer is 2 nm and the thickness of the barrier layer is 0.5 nm, the contribution rate to light emission due to the recombination within the well layer itself is only about 1.2% [=(0.3/(24+0.3)]. That is, in the present inventive concept, light emission due to recombination through quantum tunneling takes precedence over light emission due to recombination within the well layer itself, and the contribution to light emission due to the recombination through quantum tunneling exceeds the contribution to light emission due to the recombination within the well layer itself.

Referring to the data presented in FIGS. 3 and 4, the barrier layer preferably has a thickness of 1 or 2 lattice constants based on c-axis growth. Moreover, it is preferable to use InGaN, GaN, or AlGaN as a material for the barrier layer. In this case, the thickness of the well layer is not limited to less than 2 nm. In other words, the light emission mechanism of the present inventive concept is based on the phenomenon where the electrons from adjacent well layers tunnel through the barrier layer and recombine with the holes in the opposite well layer. That is, the light emission due to the recombination within the same well layer is not an important factor in the present inventive concept.

### Second Embodiment

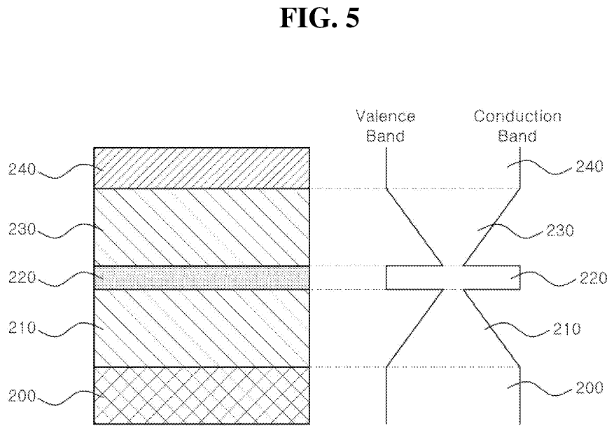

FIG. 5 shows a cross-sectional view and a bandgap diagram of a red light-emitting diode according to a second embodiment of the present inventive concept.

Referring to FIG. 5, a first semiconductor layer 200, a first well layer 210, a barrier layer 220, a second well layer 230, and a second semiconductor layer 240 are illustrated. In FIG. 5, the bandgap diagram does not reflect the effect of polarization and is shown for illustrative purposes only.

The first semiconductor layer 200 preferably has an n-type conductivity and may be formed with GaN or InGaN. For the n-type conductivity, it needs to be doped with Si. The second semiconductor layer 240 preferably has a p-type conductivity, and to this end, the second semiconductor layer 240 is doped with Mg.

The first well layer 210 is formed on the first semiconductor layer 200 and made of an InGaN material capable of emitting red light. The first well layer 210 has a concentration gradient structure where In content increases toward the top. If the In content increases, there is a potential issue with non-uniform distribution within GaN, leading to agglomeration. Furthermore, in the present inventive concept, while the recombination within a single well layer is not a critical factor, the distribution of electrons and holes at the interface of the barrier layer is a key factor. Therefore, the In content in the first well layer 210 increases as it approaches the region where the barrier layer 220 is formed, and the In content at the interface with the barrier layer 220 is selected to achieve the desired red wavelength. However, in the region adjacent to the first semiconductor layer 200, the In content is set to be relatively low. Those skilled in the art may be concerned that low In content in the region adjacent to the first semiconductor layer 200 could result in a blue shift. However, as shown in the bandgap diagram, a tilted band structure is already formed within the first well layer 210 through the gradient structure of the In concentration within the first well layer 210, which causes the electrons and holes within the first well layer 210 to be concentrated at the interface adjacent to the barrier layer 220. As a result, there is little or no blue shift.

The barrier layer 220 is formed on the first well layer 210. The barrier layer 220 is made of InGaN, GaN, or AlGaN as mentioned in FIGS. 3 and 4 of the first embodiment and should have a thickness of 0.5 nm to 1 nm or a thickness of 1 or 2 lattice constants along the c-axis. Also, the energy barrier of the barrier layer 220 is preferably set higher than the energy level of the adjacent first well layer 210. Moreover, the energy barrier of the barrier layer 220 may be smaller than the bandgap of the first well layer 210 in contact with the first semiconductor layer 200. However, if it is larger than the bandgap of the first well layer 210 in contact with the barrier layer 220, it is sufficient to obtain the tunneling effect of electrons.

The second well layer 230 is formed on the barrier layer 220. The second well layer 230 is made of InGaN in the same way as the first well layer 210 but has a gradient structure where the concentration of In decreases toward the top. That is, the first well layer 210 and the second well layer 230 have a symmetrical distribution of In centered around the barrier layer 220 with having an In concentration that allows the formation of red light at the interface with the barrier layer 220, and the In content decreases with increasing distance away from the barrier layer 220.

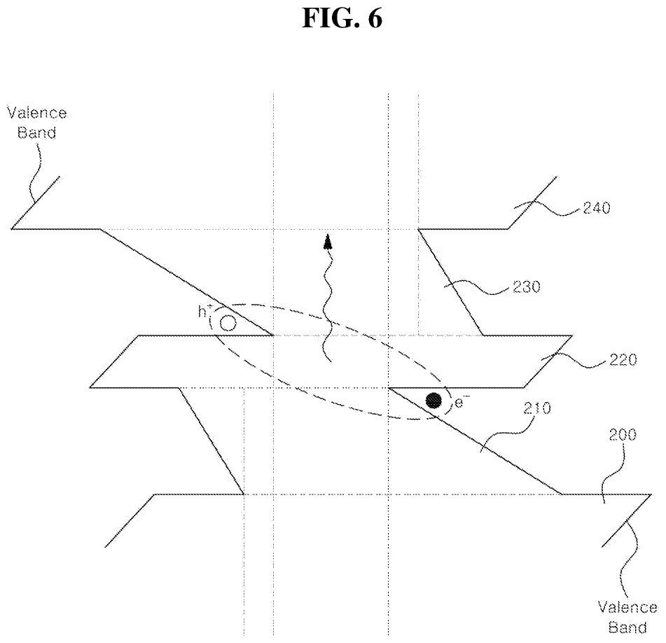

FIG. 6 is a bandgap diagram of a red light-emitting diode using a tilted band according to the second embodiment of the present inventive concept.

Referring to FIG. 6, a tilted band due to the polarization barrier of the well layer is shown, and the tilted band deepens due to the gradient structure of the In concentration. In particular, since the energy difference between the electrons and holes within the same well layer increases, the recombination probability within the same well layer decreases, and the probability of recombination of electrons and holes between adjacent well layers increases.

That is, according to Equation 1, the probability that the electrons of the conduction band of the first well layer 210 will exist at the interface of the second well layer 230 increases by quantum tunneling through the barrier layer. However, due to the gradient concentration of In, the recombination of electrons and holes in the first well layer 210 rapidly decreases away from the barrier layer 220. Accordingly, most of the electrons in the first well layer 210 also exist at the interface between the second well layer 230 and the barrier layer 220 through quantum tunneling at a specific ratio with respect to the population of electrons in the first well layer 210. In this manner, the light-emission operation is performed by recombination using quantum tunneling.

The light emission operation is the same as described in the first embodiment.

In the second embodiment, the burden of introducing a high In content into the well layer to emit red light is reduced. Specifically, an In concentration suitable for the emission of red light is only introduced in the region adjacent to the barrier layer, and the light emission operation can be performed using the electrons and holes distributed at the interfaces with the barrier layer.

Moreover, in the second embodiment, the well layers are described as having a gradual increase in the concentration of In toward the barrier layer; however, depending on the embodiment, the concentration of In may increase in a step-like fashion. In other words, if the concentration of In at the interface region in contact with the barrier layer is higher than the concentration of In in the regions away from the barrier layer, such a structure will fall within the scope of this embodiment.

In the present inventive concept, the first well layer, the barrier layer, and the second well layer are set in this order as a single light-emitting unit, but it is also possible to have a repeated structure of the first well layer and the barrier layer in this order. However, in the second embodiment, the light-emitting units of the first well layer, the barrier layer, and the second well layer in this order may be repeated in a stacked structure.

Furthermore, in the present inventive concept, the barrier layer can also be n-doped. In this case, the probability of recombination of electrons through tunneling increases. For this purpose, the barrier layer may be doped with Si.

In addition, in the present inventive concept, it can be interpreted that the barrier layer is formed over the entire area of the well layer; however, the barrier layer may be formed in certain limited regions on the surface of the well layer. Additionally, the barrier layer need not be formed on the entire surface of the well layer but may be formed as islands on the well layer or may be formed with voids. If the barrier layer is formed as islands, two well layers may directly contact each other in regions other than the island type barrier layer. If the barrier layer is formed with voids, these voids can allow the two well layers to come into direct contact with each other.

In the present inventive concept as described above, the well layer acts as a donor layer for either electrons or holes. In particular, the electrons tunnel through the barrier layer and recombine with holes in the other well layer adjacent to the barrier layer to perform a light-emission operation. In other words, the light emission within a single well layer is not primarily governed by a light emission mechanism due to recombination of electrons and holes in the same well layer; rather, it is driven by a light emission mechanism due to recombination of tunneling electrons with holes which are constrained by the polarization barrier of the other well layer. This means that it is possible to overcome limitations on the thickness of the well layer that impede achieving a high external quantum efficiency and to create a multi-quantum well structure.

By adjusting the thickness of the barrier layer and the size of the energy barrier, the electrons and holes provided by the respective well layers can recombine with a high probability, thereby increasing the external quantum efficiency. In particular, during a single-crystal growth, efforts to remove the polarization barrier are not required, and instead, there is an advantage of increasing light-emission efficiency by utilizing the polarization barrier. Furthermore, since the light emission mechanism does not primarily rely on the recombination of electrons and holes in the same well layer, limitations on the thickness of the well layer are eliminated, facilitating the formation of the well layers.

What is claimed is:

1. A red light-emitting diode comprising:
a first well layer;
a barrier layer formed on the first well layer and having a higher bandgap than the first well layer; and
a second well layer formed on the barrier layer and having a lower bandgap than the barrier layer,
wherein the first well layer and the second well layer have a tilted band structure, and wherein electrons in the first well layer recombine with holes in the second well layer through tunneling to perform a light emission operation.

2. The red light-emitting diode of claim 1, wherein the barrier layer is made of InGaN, GaN, or AlGaN.

3. The red light-emitting diode of claim 2, wherein the first well layer or the second well layer is made of InGaN and has a fraction of indium (In) that is higher than that of the barrier layer.

4. The red light-emitting diode of claim 1, wherein the light emission operation occurs at the interface region between the second well layer and the barrier layer.

5. The red light-emitting diode of claim 4, wherein the electrons in the first well layer have a probability of recombining with the holes in the second well layer according to Equation 1 below:
$${T}_{e , SIR} \approx exp [ - 2 \sqrt{\frac{2 {m}_{e} {L}^{2}}{{ℏ}^{2}} {E}_{bh}} ] \qquad [ Equation 1 ]$$
where T_{e,SIR} represents the probability that the electrons in the conduction band of the first well layer will recombine with the holes in the second well layer or the probability that the electrons from the first well layer distributed at the interface with the barrier layer will also be distributed at the interface between the second well layer and the barrier layer, mₑ represents the effective mass of electron, L is the thickness of the barrier layer, E_{bh} is the energy difference of the barrier layer as seen by the electrons in the first well layer, ℏ is h/(2π), and h is the Planck's constant.

6. The red light-emitting diode of claim 4, wherein the barrier layer is made of InGaN, GaN, or AlGaN and has a thickness of 1 or 2 lattice constants in the c-axis direction.

7. The red light-emitting diode of claim 6, wherein the barrier layer has a thickness of 0.5 nm to 1 nm.

8. The red light-emitting diode of claim 7, wherein a first contribution rate to light emission due to the recombination of the electrons in the first well layer and the holes in the second well layer is higher than a second contribution rate to light emission due to the recombination of electrons and holes within the well layer itself.

9. The red light-emitting diode of claim 8, wherein the second contribution rate is less than 22% compared to the total contribution.

10. The red light-emitting diode of claim 1, wherein the energy of the conduction band of the first well layer decreases toward the barrier layer, and the energy of the conduction band of the second well layer increases toward the barrier layer.

11. A red light-emitting diode comprising:
a first well layer made of InGaN;
a barrier layer formed on the first well layer, through which electrons of a conduction band in the first well layer can tunnel; and
a second well layer made of InGaN and formed on the barrier layer, where the tunneling electrons in the first well layer recombine with holes,
wherein the concentration of indium in the first well layer increases toward the barrier layer, and the concentration of indium in the second well layer also increase toward the barrier layer.

12. The red light-emitting diode of claim 11, wherein the first well layer has a fraction of indium (In) that emits red light at the interface region with the barrier layer.

13. The red light-emitting diode of claim 11, wherein the first well layer has a fraction of indium (In) that causes a blue shift from red light with increasing distance away from the barrier layer.

14. The red light-emitting diode of claim 11, wherein the barrier layer comprises GaN or InGaN having a fraction of indium (In) that is lower than that of the first well layer.

15. The red light-emitting diode of claim 11, wherein the light emission operation occurs at the interface region between the second well layer and the barrier layer.

16. The red light-emitting diode of claim 15, wherein the electrons in the first well layer have a probability of recombining with the holes in the second well layer according to Equation 1 below:
$${T}_{e , SIR} \approx exp [ - 2 \sqrt{\frac{2 {m}_{e} {L}^{2}}{{ℏ}^{2}} {E}_{bh}} ] \qquad [ Equation 1 ]$$
where T_{e,SIR} represents the probability that the electrons in the conduction band of the first well layer will recombine with the holes in the second well layer or the probability that the electrons from the first well layer distributed at the interface with the barrier layer will also be distributed at the interface between the second well layer and the barrier layer, mₑ represents the effective mass of electron, L is the thickness of the barrier layer, E_{bh} is the energy difference of the barrier layer as seen by the electrons in the first well layer, ℏ is h/(2π), and h is the Planck's constant.

17. The red light-emitting diode of claim 15, wherein the barrier layer is made of GaN, InGaN, or AlGaN and has a thickness of 1 or 2 lattice constants in the c-axis direction.

18. The red light-emitting diode of claim 17, wherein the barrier layer has a thickness of 0.5 nm to 1 nm.
